(19) United States
(12) Patent Application Publication
(10) Pub. No.: US 2024/0153744 A1
(43) Pub. Date: May 9, 2024

(54) ETCHING METHOD AND PLASMA PROCESSING APPARATUS

(71) Applicant: Tokyo Electron Limited, Tokyo (JP)

(72) Inventors: Atsushi TAKAHASHI, Miyagi (JP); Maju TOMURA, Miyagi (JP); Ryo MATSUBARA, Albany, NY (US)

(73) Assignee: Tokyo Electron Limited, Tokyo (JP)

(21) Appl. No.: 18/386,618

(22) Filed: Nov. 3, 2023

(30) Foreign Application Priority Data
Nov. 4, 2022 (JP) 2022-177190
Sep. 5, 2023 (JP) 2023-143774

(51) Int. Cl. H01J 37/32

(52) U.S. Cl. CPC H01J 37/32449; H01J 37/32715; H01J 37/32816; H01J 2237/3341

(57) ABSTRACT

An etching method includes: (a) providing a substrate having an etching target film and a mask on the etching target film to a substrate support in a plasma processing apparatus including a chamber, the substrate support, a plasma generator supplied with source power, and a bias electrode supplied with bias power; and (b) forming a recess by etching the etching target film. In (b), the source power and the bias power are periodically supplied in a cycle that includes a first period and a second period. In the first period, the etching target film is etched, and in the second period, the second processing gas is adsorbed onto the etching target film.

### CROSS-REFERENCE TO RELATED APPLICATIONS

This application claims the benefits of priorities from Japanese Patent Application No. 2022-177190, filed on Nov. 4, 2022, and Japanese Patent Application No. 2023-143774, filed on Sep. 5, 2023, the entire contents of each are incorporated herein by reference.

### TECHNICAL FIELD

Exemplary embodiments of the present disclosure relate to an etching method and a plasma processing apparatus.

### BACKGROUND

In the manufacture of an electronic device, plasma etching of a silicon-containing film of a substrate is performed. In the plasma etching, the etching of the silicon-containing film is performed using plasma generated from a processing gas. Patent Document 1 discloses a processing gas containing a fluorocarbon gas as a processing gas used for plasma etching of a silicon-containing film.

### CITATION LIST

### Patent Documents

Patent Document 1: US2016/0343580A

### SUMMARY

The present disclosure provides a technique of etching a film while suppressing a shape abnormality.

In one exemplary embodiment, the etching method includes: (a) providing a substrate having an etching target film and a mask on the etching target film to a substrate support in a plasma processing apparatus including a chamber, the substrate support for supporting a substrate in the chamber, a plasma generator supplied with source power, and a bias electrode supplied with bias power; and (b) forming a recess by etching the etching target film. In (b), the source power and the bias power are periodically supplied in a cycle that includes a first period in which the source power and the bias power are each supplied at a predetermined power value, and a second period in which at least one of the source power and the bias power is not supplied or is maintained at a power value lower than the power value in the first period. In the first period, the etching target film is etched by a first plasma generated from a first processing gas supplied into the chamber, and in the second period, a second processing gas supplied into the chamber is adsorbed onto the etching target film.

According to one exemplary embodiment, a technique of etching a film while suppressing a shape abnormality is provided.

### BRIEF DESCRIPTION OF DRAWINGS

FIG. 1 is a diagram schematically illustrating a plasma processing apparatus according to one exemplary embodiment.

FIG. 2 is a diagram schematically illustrating the plasma processing apparatus according to the exemplary embodiment.

FIG. 3 is a flowchart of an etching method according to the exemplary embodiment.

FIG. 4 is a cross-sectional view of an example of a substrate to which the method of FIG. 3 may be applied.

FIG. 5 is a cross-sectional view illustrating a step of the etching method according to the exemplary embodiment.

FIG. 6 is a cross-sectional view illustrating a step of the etching method according to the exemplary embodiment.

FIG. 7 is a cross-sectional view illustrating a step of the etching method according to the exemplary embodiment.

FIG. 8 is a cross-sectional view of an example of a substrate which may be manufactured by the etching method according to the exemplary embodiment.

FIG. 9 is a timing chart of an example related to the etching method according to the exemplary embodiment.

FIG. 10 is a timing chart of an example related to the etching method according to the exemplary embodiment.

FIG. 11 is a timing chart of an example related to the etching method according to the exemplary embodiment.

FIG. 12 is a timing chart of an example related to the etching method according to the exemplary embodiment.

FIG. 13 is a timing chart of an example related to the etching method according to the exemplary embodiment.

### DETAILED DESCRIPTION

Hereinafter, various exemplary embodiments will be described.

In one exemplary embodiment, the etching method includes: (a) providing a substrate having an etching target film and a mask on the etching target film to a substrate support in a plasma processing apparatus; and (b) forming a recess by etching the etching target film. The plasma processing apparatus includes a chamber, the substrate support for supporting a substrate in the chamber, a plasma generator supplied with source power for plasma generation, and a bias electrode supplied with bias power for etchant attraction.

In (b), the source power and the bias power are periodically supplied in a cycle that includes a first period and a second period. The first period is a period in which the source power and the bias power are each supplied at a predetermined power value. The second period is a period in which at least one of the source power and the bias power is not supplied or is maintained at a power value lower than the power value in the first period. Further, in the first period, the etching target film is etched by a first plasma generated from the first processing gas supplied into the chamber, and in the second period, the second processing gas supplied into the chamber is adsorbed onto the etching target film.

In the etching method, in step (b), the source power and the bias power are periodically supplied in a cycle that includes a first period and a second period. The first period is a period in which etching of the etching target film easily progresses, and the second period is a period in which etching of the etching target film is difficult to progress compared to the first period. Therefore, in the etching method, the temperature of the substrate raised by the etching in the first period can be reduced in the second period, so that the temperature of the substrate can be easily controlled.

Further, in the etching method, the second processing gas is supplied in the second period, and the second processing gas is adsorbed onto the etching target film. The second processing gas adsorbed onto the etching target film or the protective portion derived from the second processing gas suppresses etching in a direction other than the intended etching direction in the subsequent first period, so that the shape abnormality of the recess is suppressed. The intended etching direction may be referred to as a vertical direction with respect to the etching target film or a direction from the plasma generator toward the bias electrode.

In the etching method, the second processing gas may include a silylation agent having an alkyl group. In this case, the alkyl group contained in the silylation agent adsorbed onto the surface of the etching target film suppresses etching (for example, side etching) in a direction different from the intended direction, so that the shape abnormality of the recess is suppressed.

In the etching method, in the silylation agent having an alkyl group, the alkyl group may have 1 or more and 20 or less carbon atoms.

In the etching method, the silylation agent having an alkyl group may have at least one reactive group selected from the group consisting of a hydroxyl group (—OH), an alkoxy group (—OW), an aryloxy group (—OR²), an amino group (—NR³R⁴), and a halogeno group (—X) (where R¹ represents an alkyl group, R² represents an aryl group, and R³ and R⁴ each independently represent a hydrogen atom, an alkyl group, or an aryl group).

In the etching method, the silylation agent having an alkyl group may include at least one selected from the group consisting of N,N-dimethyltrimethylsilylamine, decyldimethylchlorosilane, dimethyl-n-octylchlorosilane, and decyldimethylmethoxysilane.

In the etching method, the second processing gas may include a silylation agent having an alkyl group, and the first processing gas may include a tungsten-containing gas. In this case, the silylation agent having an alkyl group is adsorbed onto the etching target film in the second period, and tungsten is captured by the alkyl group in the subsequent first period, so that the protective portion containing tungsten is formed on the etching target film. The protective portion suppresses etching (for example, side etching) in a direction different from the intended direction, so that the shape abnormality of the recess is suppressed.

In the etching method, the substrate may include a silicon nitride film, and the second processing gas may include an acid component. In this case, the acid component is adsorbed onto the etching target film in the second period, and in the subsequent first period, ammonia generated along with the etching of the silicon nitride film reacts with the acid component to form a salt. The salt formed on the etching target film suppresses etching (for example, side etching) in a direction different from the intended direction, so that the shape abnormality of the recess is suppressed.

In the etching method, the second processing gas may include an acid component, and in the second period, after the second processing gas is adsorbed onto the etching target film, a third processing gas containing a base component may be supplied into the chamber. In this case, the acid component is adsorbed onto the etching target film, and thereafter, the acid component and the base component react with each other to form a salt. The salt formed on the etching target film suppresses etching (for example, side etching) in a direction different from the intended direction, so that the shape abnormality of the recess is suppressed.

In the etching method, the acid component may include at least one selected from the group consisting of formic acid, acetic acid, HCl, HBr, HI, trichloroacetic acid, and citric acid.

In the etching method, the base component may include at least one selected from the group consisting of ammonia, dimethylamine, trimethylamine, pyridine, pyrrolidine, tetrazole, and piperazine.

In the etching method, the first processing gas may include a phosphorus-containing gas and a fluorine-containing gas. In this case, the etching target film is etched by fluorine chemical species from the plasma generated from the fluorine-containing gas. Further, in a state where phosphorus chemical species generated from the phosphorus-containing gas exists on the surface of the etching target film, the adsorption of the fluorine chemical species (that is, the etchant) generated from the fluorine-containing gas onto the etching target film is accelerated. Therefore, in the method, the phosphorus chemical species generated from the phosphorus-containing gas are adsorbed on the surface of the etching target film, so that the supply of the etchant to the etching target film (particularly, the bottom of the recess of the etching target film) is accelerated, and thus the etching rate increases.

In the etching method, the first processing gas may include a hydrogen fluoride gas.

In the etching method, the first processing gas may further include a phosphorus-containing gas.

In the etching method, the first processing gas may further include at least one selected from the group consisting of a carbon-containing gas, a metal-containing gas, an oxygen-containing gas, and a halogen-containing gas.

In the etching method, the etching target film may include a silicon-containing film.

In the etching method, pressure in the plasma processing chamber during the second period may be lower than pressure in the plasma processing chamber during the first period.

In the etching method, each of the first period and the second period may be 0.0005 seconds or more and 50 seconds or less.

In the etching method, in the first period, the first processing gas may be supplied into the chamber at a first flow rate, and in the second period, the first processing gas may not be supplied into the chamber or may be supplied at a second flow rate smaller than the first flow rate.

In the etching method, in the first period and the second period, the second processing gas may be supplied into the chamber at a third flow rate.

In one exemplary embodiment, a plasma processing apparatus includes a chamber, a substrate support for supporting a substrate in the chamber, a plasma generator (for example, an upper electrode), a bias electrode (for example, a lower electrode), a first power source, a second power source, a gas supply, and a controller. The plasma generator is supplied with source power for plasma generation. The bias electrode is supplied with bias power for etchant attraction. The first power source is connected to the plasma generator and supplies the source power to the plasma generator. The second power source is connected to the bias electrode and supplies the bias power to the bias electrode. The gas supply is configured to supply a first processing gas and a second processing gas into the chamber. The plasma generator is configured to generate a plasma from the first processing gas in the chamber.

The controller is configured to control the first power source, the second power source, the gas supply, and the plasma generator so that the source power and the bias power are periodically supplied in a cycle that includes a first period and a second period, in the first period, the first processing gas is supplied into the chamber, and in the second period, the second processing gas is supplied into the chamber. The first period is a period in which the source power and the bias power are each supplied at a predetermined power value. The second period is a period in which at least one of the source power and the bias power is not supplied or is maintained at a power value lower than the power value in the first period. In the first period, the first processing gas is supplied into the chamber, and the etching target film is etched by the plasma generated from the first processing gas. In the second period, the second processing gas is supplied into the chamber, and the second processing gas is adsorbed onto the etching target film.

According to the plasma processing apparatus, in the second period, the second processing gas may be supplied, and the second processing gas may be adsorbed onto the etching target film. The second processing gas adsorbed onto the etching target film or the protective portion derived from the second processing gas suppresses etching in a direction other than the intended etching direction in the subsequent first period, so that the shape abnormality of the recess is suppressed. The intended etching direction may be referred to as a vertical direction with respect to the etching target film or a direction from the plasma generator toward the bias electrode.

Hereinafter, various exemplary embodiments will be described in detail with reference to the drawings. In the respective drawings, there may be a case where the same reference numerals are given to like or corresponding parts.

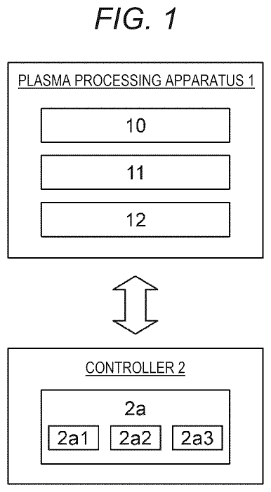

FIG. 1 is a diagram for explaining an example of a configuration of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

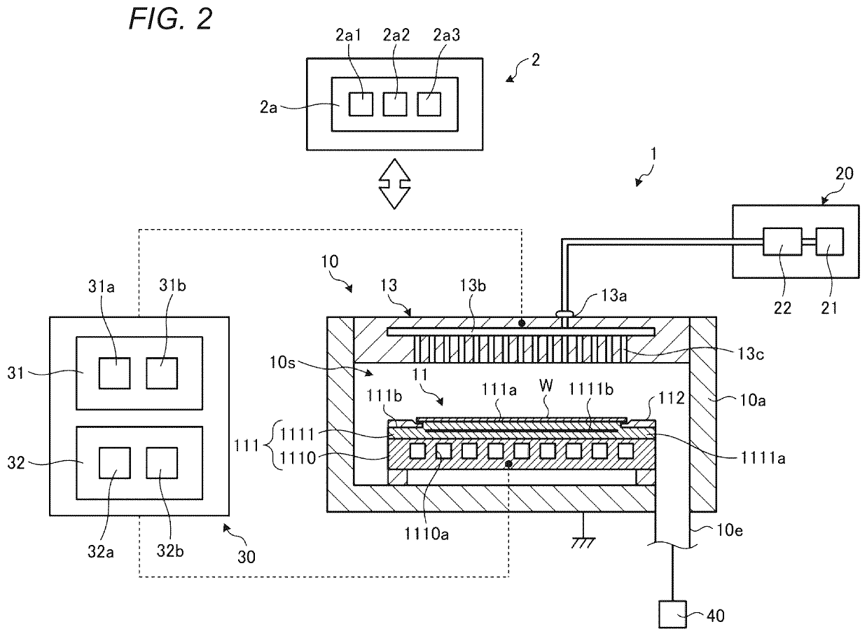

Hereinafter, a configuration example of a capacitively-coupled plasma processing apparatus as an example of the plasma processing apparatus 1 will be described. FIG. 2 is a view for explaining an example of a configuration of a capacitively-coupled plasma processing apparatus.

The capacitively-coupled plasma processing apparatus 1 includes the plasma processing chamber 10, the gas supply 20, a power source 30, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to the RF power source 31 and/or the DC power source 32 to be described later may be disposed in the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31, at least one lower electrode and/or at least one upper electrode may function as at least a part of the plasma generator 12. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is supplied to at least one lower electrode. In one embodiment, the second DC generator 32b is configured to be connected to at least one upper electrode to generate a second DC signal. The generated second DC signal is supplied to at least one upper electrode.

In various embodiments, the first and second DC signals may be pulsed. In this case, the sequence of voltage pulses is supplied to at least one lower electrode and/or at least one upper electrode. The voltage pulse may have a pulse waveform of a rectangle, a trapezoid, a triangle, or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

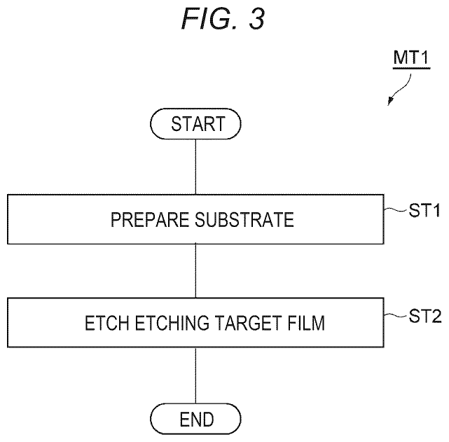

FIG. 3 is a flowchart of an etching method according to one exemplary embodiment. An etching method MT1 illustrated in FIG. 3 (hereinafter referred to as “method MT1”) may be performed by the plasma processing apparatus 1 of the embodiment. The method MT1 may be applied to a substrate W1. That is, the substrate W may be the substrate W1.

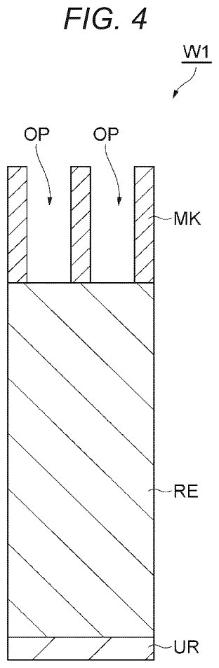

FIG. 4 is a cross-sectional view of an example of a substrate to which the method of FIG. 3 may be applied. As illustrated in FIG. 4, in one embodiment, the substrate W1 includes an etching target film RE and a mask MK on the etching target film RE. The etching target film RE may be provided on an underlying film UR. The mask MK may have at least one opening OP.

The etching target film RE may include at least one of a silicon-containing film and an organic film. The silicon-containing film may include at least one of a silicon film, a silicon germanium film, a silicon oxide film, and a silicon nitride film. The silicon oxide film may include impurities such as phosphorus, boron, and nitrogen. The silicon nitride film may include impurities such as phosphorus and boron. The silicon-containing film may be a stacked film in which a silicon oxide film and a silicon nitride film are alternately stacked. The organic film may be an amorphous carbon film. The etching target film RE may be a film for a memory device such as a DRAM or a 3D-NAND, for example.

The mask MK may include at least one of a silicon-containing substance, an organic substance, and a metal. The silicon-containing substance may include polysilicon. The organic substance may include at least one of a photoresist and a spin on carbon (SOC). The metal may include at least one selected from the group consisting of tungsten, molybdenum, titanium, and ruthenium. The mask may include carbide or silicide of the metal described above, and may include, for example, at least one selected from the group consisting of WC (tungsten carbide), WSi (tungsten silicide), WSiN, and WSiC. In a case where the etching target film RE includes a silicon-containing film, the mask MK may include at least one of a second silicon-containing substance different from the first silicon-containing substance constituting the silicon-containing film, an organic substance, and a metal. In a case where the etching target film RE includes an organic film, the mask MK may include at least one of a silicon-containing substance, a second organic substance different from the first organic substance constituting the organic film, and a metal.

The underlying film UR may include a material different from the etching target film RE. The underlying film UR may include at least one of a silicon-containing film, an organic film, and a metal-containing film.

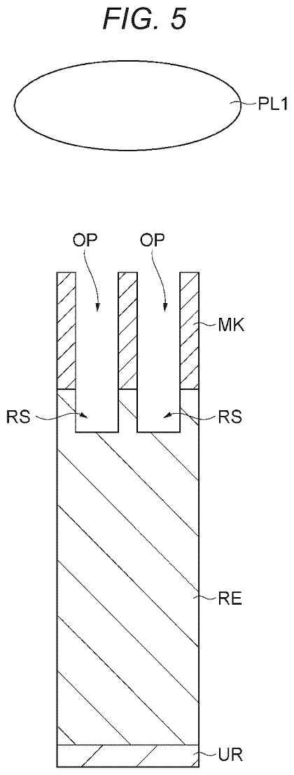

Hereinafter, the method MT1 will be described by taking as an example a case where the method MT1 is applied to the substrate W1 using the plasma processing apparatus 1 of the embodiment described above, with reference to FIGS. 3 to 8. FIGS. 5 to 7 are cross-sectional views illustrating a step of the etching method according to one exemplary embodiment. In a case where the plasma processing apparatus 1 is used, the method MT1 may be performed in the plasma processing apparatus 1 under the control of each part of the plasma processing apparatus 1 by the controller 2. In the method MT1, the substrate W (for example, substrate W1) on the substrate support 11 (substrate support) disposed in the plasma processing chamber may be processed as illustrated in FIG. 2.

As illustrated in FIG. 3, the method MT1 may include step ST1 and step ST2. Step ST1 and step ST2 may be performed sequentially.

In step ST1, the substrate W1 illustrated in FIG. 4 is provided. The substrate W1 may be loaded into the plasma processing chamber 10. The substrate W1 may be supported by the substrate support 11 in the plasma processing chamber 10.

In step ST2, the etching target film RE is etched to form a recess RS, as illustrated in FIGS. 3 to 7.

Step ST2 includes a first period and a second period. In the first period, source power for plasma generation and bias power for etchant attraction are each supplied at a predetermined power value, and the first processing gas is supplied into the chamber. In the second period, at least one of the source power and the bias power is maintained at a power value lower than the power value in the first period, and the second processing gas is supplied into the chamber.

In the first period, as illustrated in FIG. 5, the etching target film RE is etched by a first plasma PL1 generated from the first processing gas, so that a recess RS is formed. The recess RS may correspond to the opening OP of the mask MK.

The first processing gas may be a gas that may generate a plasma for etching the etching target film RE. The first processing gas may include, for example, an HF gas. The flow rate of the HF gas may be the largest in the first processing gas, excluding an inert gas. In an example, the HF gas may be 50% by volume or more, 60% by volume or more, 70% by volume or more, or 80% by volume or more with respect to the total flow rate of the first processing gas excluding the inert gas. As the HF gas, a gas with high purity, for example, a gas with 99.999% or more purity can be used.

The processing gas may include a gas capable of generating HF species in a plasma, instead of or in addition to the HF gas. The HF species includes at least any one of a gas, a radical, and an ion of hydrogen fluoride.

In an example, a hydrofluorocarbon gas may be used as the gas capable of generating the HF species. The hydrofluorocarbon gas may have 2 or more, 3 or more, or 4 or more carbon atoms. The hydrofluorocarbon gas may be used, in an example, by selecting at least one from the group consisting of a CH₂F₂ gas, a C₃H₂F₄ gas, a C₃H₂F₆ gas, a C₃H₃F₅ gas, a C₄H₂F₆ gas, a C₄H₅F₅ gas, a C₄H₂F₈ gas, a C₅H₂F₆ gas, a C₅H₂F to gas, and a C₅H₃F₇ gas. The hydrofluorocarbon gas is used, in an example, by selecting at least one from the group consisting of a CH₂F₂ gas, a C₃H₂F₄ gas, a C₃H₂F₆ gas, and a C₄H₂F₆ gas.

In an example, a fluorine-containing gas and a hydrogen-containing gas may be used as the gas capable of generating the HF species. In an example, a fluorocarbon gas may be used as the fluorine containing gas. The fluorocarbon gas may include at least one selected from the group consisting of a C₂F₂ gas, a C₂F₄ gas, a C₃F₆ gas, a C₃F₈ gas, a C₄F₆ gas, a C₄F₈ gas, and a C₅F₈ gas. In an example, an NF₃ gas or an SF₆ gas may be used as the fluorine-containing gas. In an example, an H₂ gas, a CH₄ gas, or a NH₃ gas may be used as the hydrogen-containing gas.

The first processing gas may include a phosphorus-containing gas. The phosphorus containing gas is a gas containing a phosphorus containing molecule. The phosphorus containing molecule may be an oxide, such as tetraphosphorus decaoxide (P₄O₁₀), tetraphosphorus octoxide (P₄O₈), and tetraphosphorus hexaoxide (P₄O₆). The tetraphosphorus decaoxide is sometimes called diphosphorus pentoxide (P₂O₅). The phosphorus containing molecule may be a halide (phosphorus halide), such as phosphorus trifluoride (PF₃), phosphorus pentafluoride (PF₅), phosphorus trichloride (PCl₃), phosphorus pentachloride (PCl₅), phosphorus tribromide (PBr₃), phosphorus pentabromide (PBr₅), and phosphorus iodide (PI₃). That is, the phosphorus containing molecule may contain fluorine as a halogen element, such as phosphorus fluoride. Alternatively, the phosphorus containing molecule may contain a halogen element other than fluorine, as the halogen element. The phosphorus containing molecule may be halogenated phosphoryl, such as phosphoryl fluoride (POF₃), phosphoryl chloride (POCl₃), and phosphoryl bromide (POBr₃). The phosphorus containing molecule may be phosphine (PH₃), calcium phosphide (such as Ca₃P₂), phosphoric acid (H₃PO₄), sodium phosphate (Na₃PO₄), hexafluorophosphoric acid (HPF₆), or the like. The phosphorus containing molecule may be fluorophosphines (H_{g}PFₕ). Here, the sum of g and h is 3 or 5. As the fluorophosphine, HPF₂ and H₂PF₃ are exemplified.

The first processing gas may contain one or more phosphorus-containing molecules among the phosphorus-containing molecules described above, as at least one phosphorus-containing molecule. For example, the processing gas may include at least one of PF₃, PCl₃, PF₅, PCl₅, POCl₃, PH₃, PBr₃, and PBr₅ as at least one phosphorus-containing molecule. In a case where each phosphorus-containing molecule contained in the first processing gas is a liquid or a solid, each phosphorus-containing molecule may be evaporated by heating or the like and supplied into the plasma processing chamber 10.

The first processing gas may include a carbon-containing gas. The carbon containing gas may be at least one or both of a fluorocarbon gas or a hydrofluorocarbon gas. The fluorocarbon gas may include at least one selected from the group consisting of a C₂F₂ gas, a C₂F₄ gas, a C₃F₆ gas, a C₃F₈ gas, a C₄F₆ gas, a C₄F₈ gas, and a C₅F₈ gas. The hydrofluorocarbon gas may include at least one selected from the group consisting of a CHF₃ gas, a CH₂F₂ gas, a CH₃F gas, a C₂HF₅ gas, a C₂H₂F₄ gas, a C₂H₃F₃ gas, a C₂H₄F₂ gas, a C₃HF₇ gas, a C₃H₂F₂ gas, a C₃H₂F₄ gas, a C₃H₂F₆ gas, a C₃H₃F₅ gas, a C₄H₂F₆ gas, a C₄H₅F₅ gas, a C₄H₂F₈ gas, a C₅H₂F₆ gas, a C₅H₂F₁₀ gas, and a C₅H₃F₇ gas. Further, the carbon containing gas may be a linear one having an unsaturated bond. The linear carbon-containing gas having an unsaturated bond may use, for example, at least one selected from the group consisting of a C₃F₆ (hexafluoropropene) gas, a C₄F₈ (octafluoro-1-butene, octafluoro-2-butene) gas, a C₃H₂F₄ (1,3,3,3-tetrafluoropropene) gas, a C₄H₂F₆ (trans-1,1,1,4,4,4-hexafluoro-2-butene) gas, a C₄F₈O (pentafluoroethyl trifluorovinyl ether) gas, a CF₃COF (1,2,2,2-tetrafluoroethane-1-one) gas, a CHF₂COF (difluoroacetic acid fluoride) gas, and a COF₂ (fluorinated carbonyl) gas.

The first processing gas may further include a metal-containing gas. The metal-containing gas may be a tungsten-containing gas. The tungsten-containing gas may be a gas containing tungsten and halogen, and, in an example, is a WFₐCl_{b} gas (a and b are each an integer of 0 or more and 6 or less, and a sum of a and b is 2 or more and 6 or less). Specifically, the tungsten containing gas may be a gas containing tungsten and fluorine, such as a tungsten difluoride (WF₂) gas, a tungsten tetrafluoride (WF₄) gas, a tungsten pentafluoride (WF₅) gas, or a tungsten hexafluoride (WF₆) gas, or a gas containing tungsten and chlorine, such as a tungsten dichloride (WCl₂) gas, a tungsten tetrachloride (WCl₄) gas, a tungsten pentachloride (WCl₅) gas, or a tungsten hexachloride (WCl₆) gas. Among these, at least any gas of a WF₆ gas and a WCl₆ gas may be used. The flow rate of the tungsten-containing gas may be, for example, 5% by volume or less, 1% by volume or less, 0.5% by volume or less, or 0.2% by volume or less with respect to the total flow rate of the processing gas excluding the inert gas. Further, the flow rate of the tungsten-containing gas may be, for example, 0.01% by volume or more with respect to the total flow rate of the processing gas excluding the inert gas.

As the metal-containing gas, at least one of a molybdenum-containing gas and a titanium-containing gas may be used instead of or in addition to the tungsten-containing gas.

The first processing gas may further include an oxygen-containing gas. The oxygen-containing gas may be, for example, at least one gas selected from the group consisting of O₂, CO, CO₂, H₂O, and H₂O₂. In an example, the first processing gas may be an oxygen-containing gas other than H₂O, that is, may include at least one gas selected from the group consisting of O₂, CO, CO₂, and H₂O₂. The flow rate of the oxygen containing gas may be adjusted according to the flow rate of the carbon containing gas such as a fluorocarbon gas or a hydrofluorocarbon gas.

The first processing gas may further include a halogen-containing gas. The halogen-containing gas may include, for example, at least one gas selected from the group consisting of Cl₂, Br₂, HCl, HBr, HI, BCl₃, ClF₃, IF₅, IF₇, and BrF₃. The halogen-containing gas may include carbon, and may include carbon and two or more halogens. The halogen-containing gas containing carbon may be at least one selected from the group consisting of, for example, CₓH_{y}Cl_{z}, CₓF_{y}Br_{z}, CₓF_{y}I_{z}, and CₓF_{y}Cl_{z}. Here, x and z are integers of 1 or more, and y is an integer of 0 or more. The halogen-containing gas containing carbon may include, for example, one or more gases among a CHCl₃, a CH₂Cl₂, and a CF₂Br₂.

The processing gas may further include a noble gas such as an Ar gas, a He gas, a Kr gas, or a Xe gas, or an inert gas such as a nitrogen gas.

In the first period, the first processing gas is supplied into the plasma processing chamber 10 by the gas supply 20, the source power and the bias power are each supplied at a predetermined power value, and the first plasma PL1 is generated from the first processing gas in the plasma processing chamber by the plasma generator 12. The controller 2 may control the power source 30, the gas supply 20, and the plasma generator 12 so that the etching target film RE is etched by the first plasma PL1 to form a recess RS.

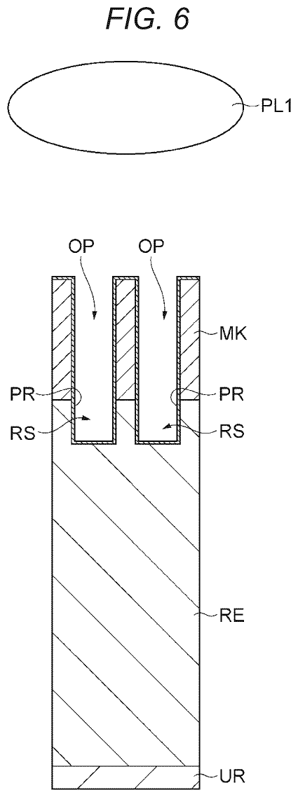

In the second period, the second processing gas supplied into the plasma processing chamber 10 is adsorbed onto the etching target film RE. In the second period, as illustrated in FIG. 6, the protective portion PR derived from the second processing gas may be formed on the etching target film RE. The protective portion PR may be formed in the first period after the second period. The second processing gas may also be adsorbed onto the mask MK, and the protective portion PR may also be formed on the mask MK. In FIG. 6, the protective portion PR is illustrated in a layered state, but the protective portion derived from the second processing gas does not necessarily need to be in a layered state. That is, the protective portion PR in FIG. 6 merely schematically illustrates the location where the protective portion derived from the second processing gas is formed, and in the method MT1, it is not necessary to form a layer corresponding to the protective portion PR on the substrate W1.

A period for purging the first processing gas supplied in the first period may be provided between the first period and the second period. Further, a period for purging the second processing gas supplied in the second period may be provided between the second period and the first period of the next cycle. The method of purging the first processing gas or the second processing gas is not particularly limited, and for example, a method of supplying an inert gas into the plasma processing chamber 10 or the like can be included. The purging time may be, for example, 1 second or more and less than 180 seconds.

In one embodiment, the second processing gas may include a silylation agent having an alkyl group. In this case, the alkyl group contained in the silylation agent adsorbed on the surface of the etching target film RE functions as the protective portion PR. The alkyl group suppresses the shape abnormality of the recess RS.

In a case where the second processing gas includes a silylation agent having an alkyl group, the etching target film RE may include a silicon-containing film and may include a silicon oxide film. Since the silicon-containing film (particularly, silicon oxide film) easily adsorbs the silylation agent, the formation of the protective portion PR by the supply of the second processing gas is facilitated.

The alkyl group contained in a silylation agent may have, for example, 1 or more and or less, 1 or more and 16 or less, 1 or more and 12 or less, 1 or more and 8 or less, or 1 or more and 4 or less carbon atoms.

The silylation agent may have a reactive group capable of forming a linking group that reacts with a hydroxyl group existing on the surface of the silicon-containing film to link a silicon atom in the silicon-containing film and an atom in the silylation agent. The linking group may be, for example, a group represented by —O—.

The reactive group may be a group that binds to a silicon atom in the silylation agent. In this case, a linking group that links the silicon atom in the silicon-containing film and the silicon atom in the silylation agent is formed. The reactive group may be, for example, a hydroxyl group (—OH), an alkoxy group (—OR), an aryloxy group (—OR²), an amino group (—NR³R⁴), a halogeno group (—X), or the like.

R¹ represents an alkyl group, and the alkyl group may have, for example, 1 or more and 20 or less, 1 or more and 16 or less, 1 or more and 12 or less, 1 or more and 8 or less, or 1 or more and 4 or less carbon atoms. R² represents an aryl group, and the aryl group may have, for example, 6 or more and 18 or less, 6 or more and 12 or less, or 6 or more and 10 or less carbon atoms. The aryl group may be, for example, a phenyl group.

R³ and R⁴ may each independently be a hydrogen atom, an alkyl group, or an aryl group, and the alkyl group may have, for example, 1 or more and 20 or less, 1 or more and 16 or less, 1 or more and 12 or less, 1 or more and 8 or less, or 1 or more and 4 or less carbon atoms. The aryl group may have, for example, 6 or more and 18 or less, 6 or more and 12 or less, or 6 or more and 10 or less carbon atoms, and the aryl group may be, for example, a phenyl group.

X represents a halogen atom. X may be, for example, a chlorine atom, a bromine atom, or an iodine atom. X may be, for example, a chlorine atom.

The boiling point of the silylation agent may be, for example, 400° C. or lower, and may be 350° C. or lower, or 300° C. or lower. Further, the boiling point of the silylation agent may be, for example, 50° C. or higher, and may be 100° C. or higher or 150° C. or higher.

Examples of the silylation agent include N,N-dimethyltrimethylsilylamine, decyldimethylchlorosilane, dimethyl-n-octylchlorosilane, and decyldimethylmethoxysilane.

In another embodiment, the second processing gas may include a silylation agent having an alkyl group, and the first processing gas may include a tungsten-containing gas. In this case, the silylation agent is adsorbed onto the etching target film RE in the second period, and the alkyl group contained in the silylation agent and the tungsten-containing gas react with each other in the subsequent first period, so that the protective portion PR containing tungsten is formed on the etching target film RE. The silylation agent and the tungsten-containing gas may be as described above.

In still another embodiment, the second processing gas may include an acid component, and the substrate may include a silicon nitride film. In this case, the acid component is adsorbed onto the etching target film RE in the second period, and in the subsequent first period, ammonia generated along with the etching of the silicon nitride film reacts with the acid component. As a result, a salt, which is a reactant of the acid component and ammonia, adheres onto the etching target film RE, and the salt functions as the protective portion PR.

The acid component may be, for example, an inorganic acid or an organic acid. When the acid component is an organic acid and the boiling point is low, the acid component is easily supplied as a gas. From this point of view, the acid component may be, for example, formic acid, acetic acid, HCl, HBr, HI, trichloroacetic acid, citric acid, or the like. The boiling point of the acid component may be, for example, 300° C. or lower. The boiling point of the acid component may be, for example, −100° C. or higher.

In yet still another embodiment, in the second period, after the second processing gas containing the acid component is supplied into the plasma processing chamber 10, the third processing gas containing the base component may be supplied into the plasma processing chamber 10. In this case, the acid component adsorbed onto the etching target film RE reacts with the base component supplied as the third processing gas, so that a salt, which is a reactant of the acid component and the base component, adheres to the etching target film RE, and the salt functions as the protective portion PR. The acid component may be as described above.

The base component may be an organic base. The base component may be an organic base that does not contain halogen. The base component is easily supplied as a gas when the boiling point is low. The boiling point of the base component may be, for example, 300° C. or lower. The boiling point of the base component may be, for example, −50° C. or higher. The base component may be, for example, ammonia, an amine (for example, dimethylamine, trimethylamine, or the like), a nitrogen-containing heterocyclic compound (for example, pyridine, pyrrolidine, tetrazole, piperazine, or the like), or the like.

In the second period, at least one of the source power and the bias power is not supplied, or is maintained at a power value lower than the power value in the first period. In the second period, etching may be substantially stopped. In the second period, the plasma may be generated, or the plasma may not be generated.

In the second period, the power value of at least one of the source power and the bias power becomes low, and thus the second processing gas is supplied into the plasma processing chamber 10 by the gas supply 20. The controller 2 may control the power source 30, the gas supply 20, and the plasma generator 12 so that the etching is interrupted and the second processing gas is adsorbed onto the etching target film RE.

In the second period, the pressure in the plasma processing chamber 10 may be reduced compared to the first period. As a result, the temperature of the substrate in the plasma processing chamber 10 can be efficiently reduced.

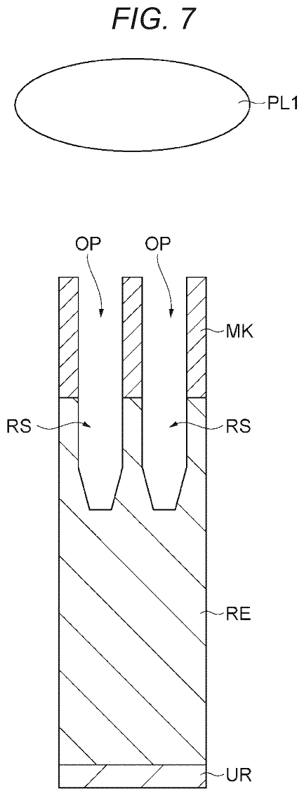

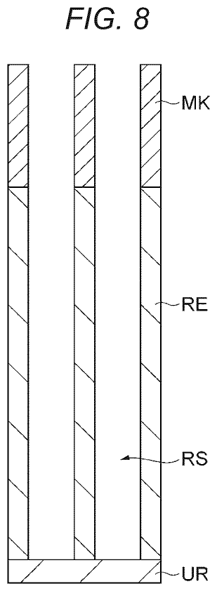

In step ST2, a cycle including the first period and the second period is repeatedly executed. In the first period after the second period, as illustrated in FIG. 7, the etching target film RE is etched by the first plasma PL1 generated from the first processing gas, so that the recess RS becomes deeper. At this time, since the etching to the sidewall of the recess RS is suppressed by the protective portion PR, it is possible to deepen the recess RS while suppressing the dimensional change of the sidewall in the vicinity of the opening of the recess RS. Therefore, according to the method MT1, as illustrated in FIG. 8, the substrate W1 having the recess RS in which the shape abnormality is suppressed and the dimensional difference between the upper portion and the lower portion is small may be manufactured. The dimension of the recess RS at the upper end of the recess RS may be 100 nm or less. The bottom of the recess RS may or may not reach the underlying film UR.

The aspect ratio of the recess RS may be, for example, 5 or more, and may be 10 or more, 20 or more, 30 or more, 40 or more, or 50 or more. The aspect ratio of the recess RS may be, for example, 200 or less. The aspect ratio of the recess RS indicates the ratio of the depth of the recess RS to the maximum width dimension of the recess RS.

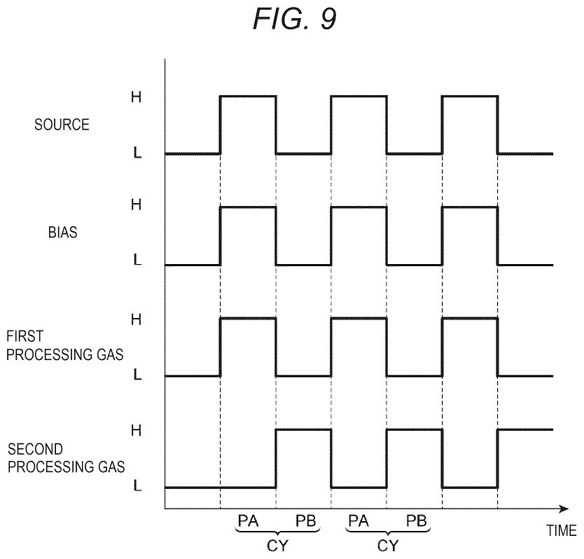

FIGS. 9 to 13 are examples of timing charts illustrating time changes of the power values of the source power and the bias power, and time changes of the supply amounts of the first processing gas and the second processing gas. These timing charts relate to step ST2.

The source power may be, for example, the source RF power supplied from the first RF generator 31a of the plasma processing apparatus 1. The bias power may be, for example, the bias RF power supplied from the second RF generator 31b of the plasma processing apparatus 1.

As illustrated in FIG. 9, in step ST2, the pulse of the source power may be supplied, and the pulse of the bias power may be supplied. The source power and the bias power may be periodically supplied in a cycle CY. The cycle CY may include a first period PA and a second period PB. In FIG. 9, the first period PA is described to be performed first, and the second period PB is described to be performed later. However, in step ST2, the second period PB may be performed first, and the first period PA may be performed later. In the first period PA, the source power and the bias power may be maintained at high power H. In the second period PB, the source power and the bias power may be maintained at low power L. The low power L may be OW. In the first period PA, the first processing gas may be maintained at a high supply amount H, and the second processing gas may be maintained at a low supply amount L. In the second period PB, the first processing gas may be maintained at a low supply amount L, and the second processing gas may be maintained at a high supply amount H. The low supply amount L may be zero (0).

The time of the first period PA may be, for example, 0.0005 seconds or more, or may be 0.005 seconds or more. Further, the time of the first period PA may be, for example, 50 seconds or less, or may be 5 seconds or less. The time of the second period PB may be, for example, 0.0005 seconds or more, or may be 0.005 seconds or more. Further, the time of the second period PB may be, for example, 50 seconds or less, or may be 5 seconds or less. The time of the cycle CY may be, for example, 0.001 seconds or more, or may be 0.01 seconds or more. Further, the time of the cycle CY may be, for example, 100 seconds or less, or may be 10 seconds or less.

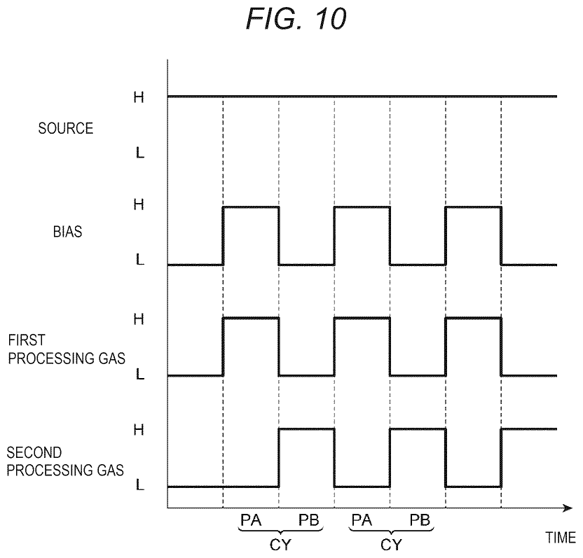

As illustrated in FIG. 10, in step ST2, the continuous wave of the source power may be supplied, and the pulse of the bias power may be supplied. The source power and the bias power may be periodically supplied in a cycle CY. The cycle CY may include a first period PA and a second period PB. In FIG. 10, the first period PA is described to be performed first, and the second period PB is described to be performed later. However, in step ST2, the second period PB may be performed first, and the first period PA may be performed later. In the first period PA, the source power and the bias power may be maintained at high power H. In the second period PB, the source power may be maintained at high power H, and the bias power may be maintained at low power L. The low power L may be OW. In the first period PA, the first processing gas may be maintained at a high supply amount H, and the second processing gas may be maintained at a low supply amount L. In the second period PB, the first processing gas may be maintained at a low supply amount L, and the second processing gas may be maintained at a high supply amount H. The low supply amount L may be zero (0).

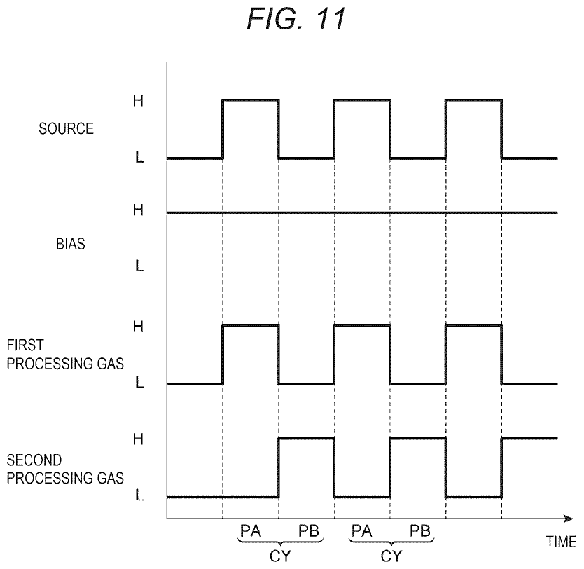

As illustrated in FIG. 11, in step ST2, the pulse of the source power may be supplied, and the continuous wave of the bias power may be supplied. The source power and the bias power may be periodically supplied in a cycle CY. The cycle CY may include a first period PA and a second period PB. In FIG. 11, the first period PA is described to be performed first, and the second period PB is described to be performed later. However, in step ST2, the second period PB may be performed first, and the first period PA may be performed later. In the first period PA, the source power and the bias power may be maintained at high power H. In the second period PB, the source power may be maintained at low power L, and the bias power may be maintained at high power H. The low power L may be OW. In the first period PA, the first processing gas may be maintained at a high supply amount H, and the second processing gas may be maintained at a low supply amount L. In the second period PB, the first processing gas may be maintained at a low supply amount L, and the second processing gas may be maintained at a high supply amount H. The low supply amount L may be zero (0).

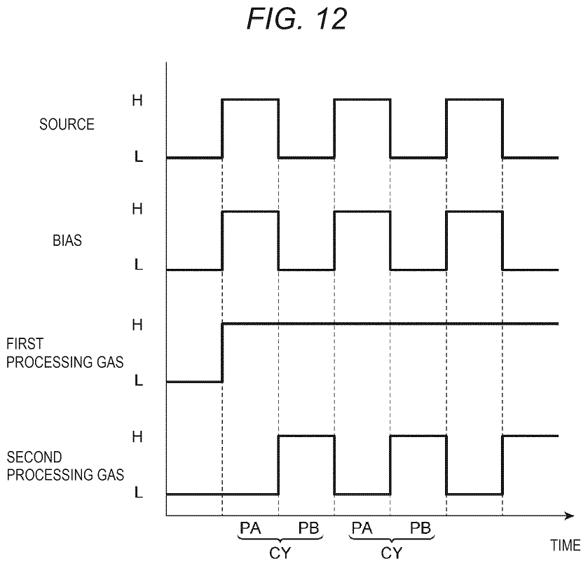

As illustrated in FIG. 12, in step ST2, the pulse of the source power may be supplied, and the pulse of the bias power may be supplied. The source power and the bias power may be periodically supplied in a cycle CY. The cycle CY may include a first period PA and a second period PB. In FIG. 12, the first period PA is described to be performed first, and the second period PB is described to be performed later. However, in step ST2, the second period PB may be performed first, and the first period PA may be performed later. In the first period PA, the source power and the bias power may be maintained at high power H. In the second period PB, the source power and the bias power may be maintained at low power L. The low power L may be OW. In the first period PA, the first processing gas may be maintained at a high supply amount H, and the second processing gas may be maintained at a low supply amount L. In the second period PB, the first processing gas and the second processing gas may be maintained at a high supply amount H. The low supply amount L may be zero (0).

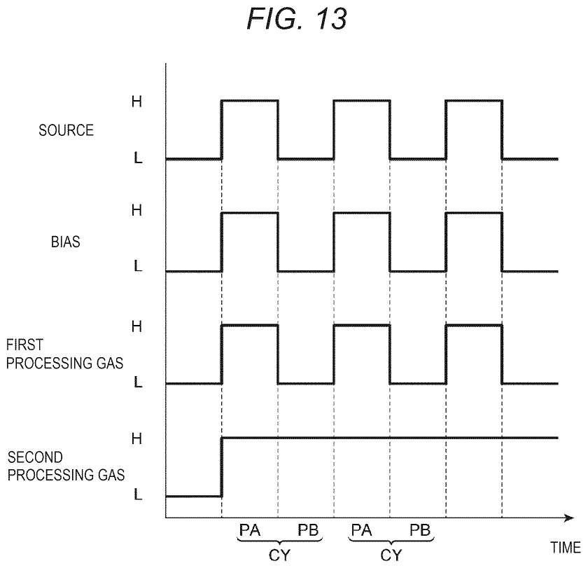

As illustrated in FIG. 13, in step ST2, the pulse of the source power may be supplied, and the pulse of the bias power may be supplied. The source power and the bias power may be periodically supplied in a cycle CY. The cycle CY may include a first period PA and a second period PB. In FIG. 13, the first period PA is described to be performed first, and the second period PB is described to be performed later. However, in step ST2, the second period PB may be performed first, and the first period PA may be performed later. In the first period PA, the source power and the bias power may be maintained at high power H. In the second period PB, the source power and the bias power may be maintained at low power L. The low power L may be OW. In the first period PA, the first processing gas and the second processing gas may be maintained at a high supply amount H. In the second period PB, the first processing gas may be maintained at a low supply amount L, and the second processing gas may be maintained at a high supply amount H. The low supply amount L may be zero (0).

In any cases of FIGS. 9 to 13, the high power H in the source power and the high power H in the bias power do not need to be the same value, and may be the same or different. Further, the low power L in the source power and the low power L in the bias power do not need to be the same value, and may be the same or different. Further, the high supply amount H in the first processing gas and the high supply amount H in the second processing gas do not need to be the same value, and may be the same or different. Further, the low supply amount L in the first processing gas and the low supply amount L in the second processing gas do not need to be the same value, and may be the same or different.

While various exemplary embodiments have been described above, various additions, omissions, substitutions and changes may be made without being limited to the exemplary embodiments described above. Also, the other embodiments may be formed by combining elements in different embodiments.

Hereinafter, various exemplary embodiments included in the present disclosure will be described in [E1] to [E20].

### [E1]

An etching method including:
(a) providing a substrate having an etching target film and a mask on the etching target film to a substrate support in a plasma processing apparatus including a chamber, the substrate support for supporting a substrate in the chamber, a plasma generator supplied with source power, and a bias electrode supplied with bias power; and
(b) forming a recess by etching the etching target film,
in which in the (b), the source power and the bias power are periodically supplied in a cycle that includes a first period in which the source power and the bias power are each supplied at a predetermined power value, and a second period in which at least one of the source power and the bias power is not supplied or is maintained at a power value lower than the power value in the first period,
in the first period, the etching target film is etched by a first plasma generated from a first processing gas supplied into the chamber, and
in the second period, a second processing gas supplied into the chamber is adsorbed onto the etching target film.

### [E2]

The etching method according to [E1], in which the second processing gas includes a silylation agent having an alkyl group.

### [E3]

The etching method according to [E2], in which in the silylation agent having an alkyl group, the alkyl group has 1 or more and 20 or less carbon atoms.

### [E4]

The etching method according to [E2], in which the silylation agent having an alkyl group has at least one reactive group selected from the group consisting of a hydroxyl group (—OH), an alkoxy group (—OR), an aryloxy group (—OR²), an amino group (—NR³R⁴), and a halogeno group (—X) (where R l represents an alkyl group, R² represents an aryl group, and R³ and R⁴ each independently represent a hydrogen atom, an alkyl group, or an aryl group).

### [E5]

The etching method according to [E2], in which the silylation agent having an alkyl group includes at least one selected from the group consisting of N,N-dimethyltrimethylsilylamine, decyldimethylchlorosilane, dimethyl-n-octylchlorosilane, and decyldimethylmethoxysilane.

### [E6]

The etching method according to [E1], in which the second processing gas includes a silylation agent having an alkyl group, and
the first processing gas includes a tungsten-containing gas.

### [E7]

The etching method according to [E1], in which the substrate includes a silicon nitride film, and
the second processing gas includes an acid component.

### [E8]

The etching method according to [E1], in which the second processing gas includes an acid component, and
in the second period, after the second processing gas is adsorbed onto the etching target film, a third processing gas containing a base component is supplied into the chamber.

### [E9]

The etching method according to [E7] or [E8], in which the acid component includes at least one selected from the group consisting of formic acid, acetic acid, HCl, HBr, HI, trichloroacetic acid, and citric acid.

### [E10]

The etching method according to [E8], in which the base component includes at least one selected from the group consisting of ammonia, dimethylamine, trimethylamine, pyridine, pyrrolidine, tetrazole, and piperazine.

### [E11]

The etching method according to any one of [E1] to [E5], in which the first processing gas includes a phosphorus-containing gas and a fluorine-containing gas.

### [E12]

The etching method according to [E1], in which the first processing gas includes a hydrogen fluoride gas.

### [E13]

The etching method according to [E12], in which the first processing gas further includes a phosphorus-containing gas.

### [E14]

The etching method according to [E12], in which the first processing gas further includes at least one selected from the group consisting of a carbon-containing gas, a metal-containing gas, an oxygen-containing gas, and a halogen-containing gas.

### [E15]

The etching method according to [E1], in which the etching target film includes a silicon-containing film.

### [E16]

The etching method according to [E1], in which pressure in the plasma processing chamber during the second period is lower than pressure in the plasma processing chamber during the first period.

### [E17]

The etching method according to [E1], in which each of the first period and the second period is 0.0005 seconds or more and 50 seconds or less.

### [E18]

The etching method according to [E1], in which in the first period, the first processing gas is supplied into the chamber at a first flow rate, and in the second period, the first processing gas is not supplied into the chamber or is supplied at a second flow rate smaller than the first flow rate.

### [E19]

The etching method according to [E18], in which in the first period and the second period, the second processing gas is supplied into the chamber at a third flow rate.

### [E20]

A plasma processing apparatus including:
a chamber;
a substrate support for supporting a substrate in the chamber, in which the substrate has an etching target film including a silicon-containing film and a mask on the etching target film;
a gas supply configured to supply a first processing gas and a second processing gas into the chamber;
a plasma generator configured to be supplied with source power and generate a plasma from the first processing gas in the chamber;
a bias electrode supplied with bias power;
a first power source connected to the plasma generator and configured to supply the source power to the plasma generator;
a second power source connected to the bias electrode and configured to supply the bias power to the bias electrode; and
a controller,
in which the controller is configured to control the first power source, the second power source, the gas supply, and the plasma generator so that
the source power and the bias power are periodically supplied in a cycle that includes a first period in which the source power and the bias power are each supplied at a predetermined power value, and a second period in which at least one of the source power and the bias power is not supplied or is maintained at a power value lower than the power value in the first period,
in the first period, the first processing gas is supplied into the chamber and the etching target film is etched by the plasma generated from the first processing gas, and
in the second period, the second processing gas is supplied into the chamber and the second processing gas is adsorbed onto the etching target film.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. An etching method comprising:
(a) providing a substrate having an etching target film and a mask on the etching target film to a substrate support in a plasma processing apparatus including a chamber, the substrate support for supporting a substrate in the chamber, a plasma generator supplied with source power, and a bias electrode supplied with bias power; and
(b) forming a recess by etching the etching target film,
wherein in the (b), the source power and the bias power are periodically supplied in a cycle that includes a first period in which the source power and the bias power are each supplied at a predetermined power value, and a second period in which at least one of the source power and the bias power is not supplied or is maintained at a power value lower than the power value in the first period,
in the first period, the etching target film is etched by a first plasma generated from a first processing gas supplied into the chamber, and
in the second period, a second processing gas supplied into the chamber is adsorbed onto the etching target film.

2. The etching method according to claim 1,
wherein the second processing gas includes a silylation agent having an alkyl group.

3. The etching method according to claim 2,
wherein in the silylation agent having an alkyl group, the alkyl group has 1 or more and 20 or less carbon atoms.

4. The etching method according to claim 2,
wherein the silylation agent having an alkyl group has at least one reactive group selected from the group consisting of a hydroxyl group (—OH), an alkoxy group (—OW), an aryloxy group (—OR²), an amino group (—NR³R⁴), and a halogeno group (—X) (where R¹ represents an alkyl group, R² represents an aryl group, and R³ and R⁴ each independently represent a hydrogen atom, an alkyl group, or an aryl group).

5. The etching method according to claim 2,
wherein the silylation agent having an alkyl group includes at least one selected from the group consisting of N,N-dimethyltrimethylsilylamine, decyldimethylchlorosilane, dimethyl-n-octylchlorosilane, and decyldimethylmethoxysilane.

6. The etching method according to claim 1,
wherein the second processing gas includes a silylation agent having an alkyl group, and
the first processing gas includes a tungsten containing gas.

7. The etching method according to claim 1,
wherein the substrate includes a silicon nitride film, and
the second processing gas includes an acid component.

8. The etching method according to claim 1,
wherein the second processing gas includes an acid component, and
in the second period, after the second processing gas is adsorbed onto the etching target film, a third processing gas containing a base component is supplied into the chamber.

9. The etching method according to claim 8,
wherein the acid component includes at least one selected from the group consisting of formic acid, acetic acid, HCl, HBr, HI, trichloroacetic acid, and citric acid.

10. The etching method according to claim 8,
wherein the base component includes at least one selected from the group consisting of ammonia, dimethylamine, trimethylamine, pyridine, pyrrolidine, tetrazole, and piperazine.

11. The etching method according to claim 1,
wherein the first processing gas includes a phosphorus-containing gas and a fluorine-containing gas.

12. The etching method according to claim 1,
wherein the first processing gas includes a hydrogen fluoride gas.

13. The etching method according to claim 12,
wherein the first processing gas further includes a phosphorus-containing gas.

14. The etching method according to claim 12,
wherein the first processing gas further includes at least one selected from the group consisting of a carbon-containing gas, a metal-containing gas, an oxygen-containing gas, and a halogen-containing gas.

15. The etching method according to claim 1,
wherein the etching target film includes a silicon-containing film.

16. The etching method according to claim 1,
wherein pressure in the plasma processing chamber during the second period is lower than pressure in the plasma processing chamber during the first period.

17. The etching method according to claim 1,
wherein each of the first period and the second period is 0.0005 seconds or more and 50 seconds or less.

18. The etching method according to claim 1,
wherein in the first period, the first processing gas is supplied into the chamber at a first flow rate, and
in the second period, the first processing gas is not supplied into the chamber or is supplied at a second flow rate smaller than the first flow rate.

19. The etching method according to claim 18,
wherein in the first period and the second period, the second processing gas is supplied into the chamber at a third flow rate.

20. A plasma processing apparatus comprising:
a chamber;
a substrate support for supporting a substrate in the chamber, in which the substrate has an etching target film including a silicon-containing film and a mask on the etching target film;
a gas supply configured to supply a first processing gas and a second processing gas into the chamber;
a plasma generator configured to be supplied with source power and generate a plasma from the first processing gas in the chamber;
a bias electrode supplied with bias power;
a first power source connected to the plasma generator and configured to supply the source power to the plasma generator;
a second power source connected to the bias electrode and configured to supply the bias power to the bias electrode; and
a controller,
wherein the controller is configured to control the first power source, the second power source, the gas supply, and the plasma generator so that
the source power and the bias power are periodically supplied in a cycle that includes a first period in which the source power and the bias power are each supplied at a predetermined power value, and a second period in which at least one of the source power and the bias power is not supplied or is maintained at a power value lower than the power value in the first period,
in the first period, the first processing gas is supplied into the chamber and the etching target film is etched by the plasma generated from the first processing gas, and
in the second period, the second processing gas is supplied into the chamber and the second processing gas is adsorbed onto the etching target film.
